(19) United States
(12) Patent Application Publication
(10) Pub. No.: US 2010/0201451 A1
(43) Pub. Date: Aug. 12, 2010

(54) METHOD AND SYSTEM FOR FREQUENCY CALIBRATION OF A VOLTAGE CONTROLLED RING OSCILLATOR

(76) Inventor: Stephen Wu, Fountain Valley, CA (US)

Correspondence Address: MCANDREWS HELD & MALLOY, LTD, 500 WEST MADISON STREET, SUITE 3400, CHICAGO, IL, 60661, US

(21) Appl. No.: 12/367,280

(22) Filed: Feb. 6, 2009

(51) Int. Cl. H03L 7/00

(52) U.S. Cl. 331/2

(57) ABSTRACT

Aspects of a method and system for frequency calibration of a voltage controlled ring oscillator are provided. In this regard, an oscillating voltage may be generated via a voltage controlled ring oscillator comprising a plurality of delay cells. Each of the plurality of delay cells may comprise a MOSFET differential pair coupled to a plurality of variable resistors. A frequency of oscillation and amplitude of the generated oscillating voltage may be controlled by controlling a resistance of the plurality of variable resistors. The frequency of oscillation and amplitude may be controlled via one or more digital control words generated by a baseband processor, a DSP, and/or a memory. The digital control words may comprise a control word for finely tuning the frequency of oscillation and amplitude and a control word for coarsely tuning the frequency of oscillation and amplitude.

### CROSS-REFERENCE TO RELATED APPLICATIONS/INCORPORATION BY REFERENCE

This patent application makes reference to U.S. patent application Ser. No. 11/680,883 (Attorney Docket No. 18206US01) filed on Mar. 1, 2007.

The above stated application is hereby incorporated herein by reference in its entirety.

### FIELD OF THE INVENTION

Certain embodiments of the invention relate to signal processing. More specifically, certain embodiments of the invention relate to a method and system for frequency calibration of a ring-oscillator VCO.

### BACKGROUND OF THE INVENTION

A circuit that generates a signal for which an oscillating frequency of the signal is proportional to an applied voltage may be referred to as a voltage controlled oscillator (VCO). The value of the VCO gain, Kvco, may control the amount by which the oscillating frequency of a time-varying signal generated by a VCO may change based on a change in the voltage level of a control signal.

VCOs may be used in a wide variety of applications and they may be a main building block of Phase-Locked Loops (PLLs). PLLs are electronic feedback circuits that may be used to track, for example, the frequency changes in an FM modulated signal and may be used as demodulator and a variety of other applications in communication systems.

Some VCO implementations may use LC circuits for the oscillating element. However, inductors are physically large in size, especially when compared to the size of today's Integrated Circuits (ICs).

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for frequency calibration of a voltage controlled ring oscillator, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1A is a block diagram of an exemplary communication device, in accordance with an embodiment of the invention.

FIG. 1B is a block diagram of an electronic device comprising an exemplary PLL, in accordance with an embodiment of the invention.

FIG. 2A is a block diagram illustrating an exemplary time-delay voltage-controlled oscillator, in accordance with an embodiment of the invention.

FIG. 2B is a diagram illustrating timing associated with the time-delay voltage controlled oscillator of FIG. 2A, in accordance with an embodiment of the invention.

FIG. 3 is a block diagram illustrating an exemplary voltage-controlled ring oscillator comprising a plurality of oscillator stages, in accordance with an embodiment of the invention.

FIG. 4 is a circuit diagram illustrating an exemplary stage of a ring-oscillator, in accordance with an embodiment of the invention.

FIG. 5 is a flowchart illustrating frequency calibration of a PLL comprising voltage controlled ring oscillator, in accordance with an embodiment of the invention.

### DETAILED DESCRIPTION OF THE INVENTION

Certain embodiments of the invention may be found in a method and system for frequency calibration of a voltage controlled ring oscillator. In various embodiments of the invention, an oscillating voltage may be generated via a voltage controlled ring oscillator comprising a plurality of delay cells. Each of the plurality of delay cells may comprise a MOSFET differential pair coupled to a plurality of variable resistors. A frequency of oscillation and amplitude of the generated oscillating voltage may be controlled by controlling a resistance of the plurality of variable resistors. The MOSFET differential pair may be controlled via a differential input voltage. In this regard, the differential input voltage of each delay cell may be an output voltage of another delay cell. The frequency of oscillation and amplitude of the generated oscillating voltage may be controlled via one or more digital control words generated by a baseband processor, a DSP, and/or a memory. The digital control words may comprise a control word for fine tuning frequency of oscillation and amplitude of the generated oscillating voltage and a control word for coarse tuning the frequency of oscillation and amplitude of the generated oscillating voltage. The one or more digital control words may be retrieved from a look-up table. The one or more digital control words may be initialized to a default value. The one or more control words may be adjusted such that a lock range of a PLL utilizing the voltage controlled ring oscillator may be centered on a frequency of an input signal of the phase locked loop. The one or more control words may be swept over a range of values until a phase locked loop utilizing the voltage controlled ring oscillator is phase locked. The frequency of oscillation of the generated oscillating voltage may be adjusted via a feedback path of a phase locked loop utilizing the voltage controlled ring oscillator.

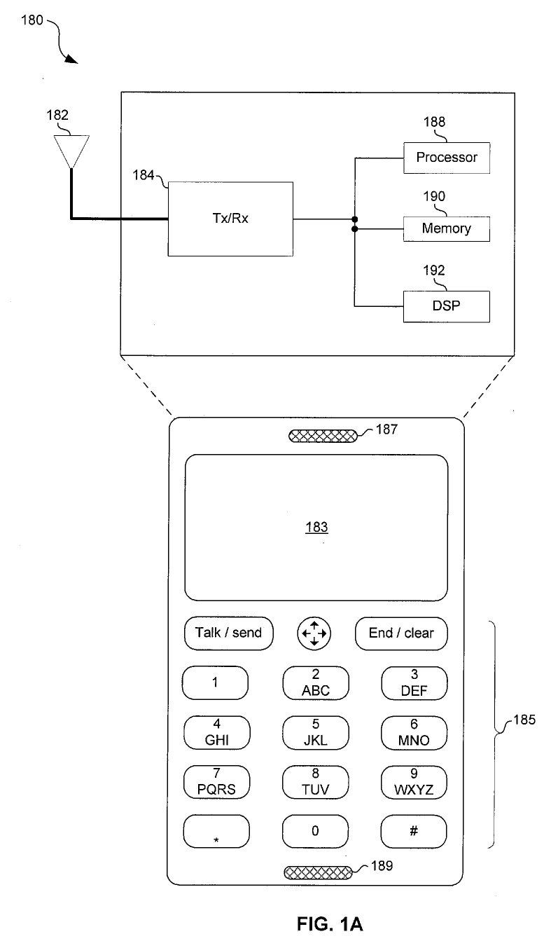

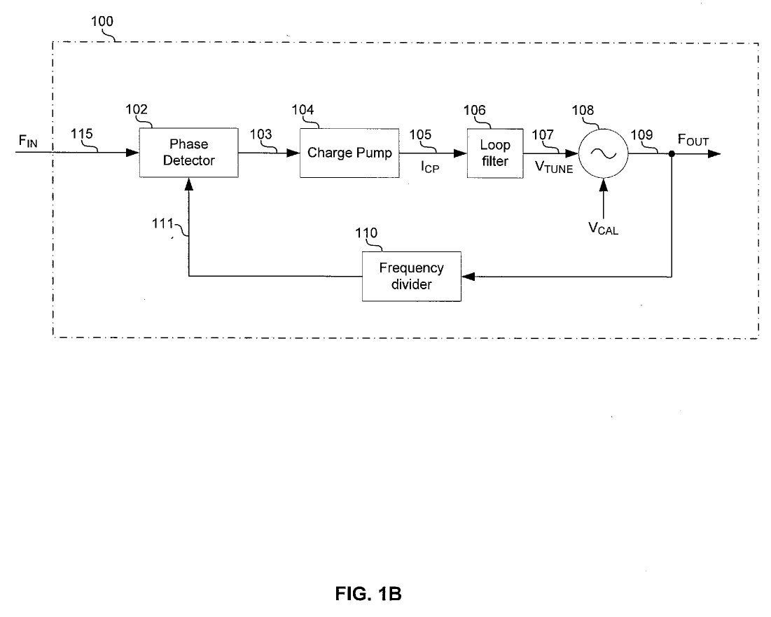

FIG. 1A is a block diagram of an exemplary communication device, in accordance with an embodiment of the invention. The communication device 180 may comprise an antenna 182, a transmitter and/or receiver (Tx/Rx) 184, a processor 188, a memory 190, a DSP 192, a display 183, user controls 185, a speaker 187, and a microphone 189.

The antenna 182 may be suitable for transmitting and/or receiving electromagnetic signals. Although a single antenna is illustrated, the invention is not so limited. In this regard, the Tx/Rx 184 may utilize a common antenna for transmission and reception of signals adhering to one or more wireless standards, may utilize different antennas for each supported wireless standard, and/or may utilize a plurality of antennas for each supported wireless standard.

The Tx/Rx 184 may comprise suitable logic circuitry and/or code that may be operable to transmit and/or receive data utilizing one or more wired, wireless, and/or optical standards. In various exemplary embodiments of the invention, the Tx/Rx 124 may be operable to communicate in adherence with cellular, WiMAX, Wi-Fi, Bluetooth, Zigbee, T1/E1, Ethernet, USB, IEEE 1394, analog audio standards, analog video standards, digital audio standards, and/or digital video standards. The Tx/Rx 184 may be operable to perform amplification, down-conversion, filtering, demodulation, and analog to digital conversion of received signals. The Tx/Rx 184 may be operable to perform amplification, up-conversion, filtering, modulation, and digital to analog conversion of signals to be transmitted. In various embodiments of the inventions, one or more carrier, reference, and/or clock frequencies utilized by the Tx/Rx 184 for transmitting and/or receiving data may be generated via a PLL comprising a digitally calibrated and/or programmable voltage controlled ring oscillator. In this regard, a frequency generated by a PLL in the device 180 may be configured based on a communication standard being utilized by the device 180.

The processor 188 may comprise suitable logic, circuitry, and/or code that may enable processing data and/or controlling operations of the communication device 180. In this regard, the processor 188 may be enabled to provide control signals to the various other portions comprising the communication device 180. The processor 188 may also control transfers of data between various portions of the communication device 180. Additionally, the processor 188 may enable execution of applications, programs, and/or code for processing data and/or effectuating operation of the communication device 180. In various embodiments of the invention, the processor 188 may generate a digital value to electronically control or tune the frequency of a voltage controlled ring oscillator utilized to generate one or more periodic signals in the communication device 180. In this regard, the processor 188 may digitally configure a PLL based on one or more frequencies being utilized within, or a mode of operation of, the communication device 180.

The memory 190 may comprise suitable logic, circuitry, and/or code that may enable storage or programming of information comprising parameters and/or code that may effectuate the operation of the communication device 180. Stored information may comprise received data and/or data to be presented, transmitted, and/or otherwise processed. The parameters may comprise configuration data and the code may comprise operational code such as software and/or firmware, but the information need not be limited in this regard. For example, the memory 190 may store a look-up table comprising digital values that may be retrieved to digitally program a frequency divider of a PLL circuit, or to digitally control the frequency of the voltage controlled ring oscillator.

The DSP 192 may comprise suitable logic, circuitry, and/or code operable to perform computationally intensive processing of data. In various embodiments of the invention, the DSP 192 may encode, decode, transcode, modulate, demodulate, encrypt, decrypt, scramble, descramble, and/or otherwise process data. In various embodiments of the invention, the DSP 192 may perform calculations and/or process data to electronically calibrate or control the frequency of a voltage controlled ring oscillator that may generate one or more periodic signals in the communication device 180.

The display 183 may be operable to provide visual information to, and/or enable interaction by, a user of the communication device 180. In various embodiments of the invention, a graphical user interface may be presented via the display 183. In various embodiments of the invention, a visual media content such as video, images, and text may be presented via the display 183.

The user controls 185 may be operable to enable user interaction with the communication device 180 to control services and/or content handled by the communication device 180. The user controls 185 may comprise, for example, a keypad, a keyboard, a roller ball, a multidirectional button, a scroll wheels, and/or a touch screen.

The speaker 187 may be operable to present audio information to a user. The speaker may present voice from a phone call and/or music or ringtones played back by the cellular enabled communication device.

The microphone 189 may be operable to convert acoustic signals into electronic signals. The microphone may enable a user to participate in a phone call and/or interact with the cellular enabled communication device via oral input.

In operation, the Tx/Rx 184 may receive data formatted according to one or more communication standards, process the data, and output digital baseband data to the processor 188, the memory 190, and/or the DSP 192. The digital baseband data may be processed by the processor 188, the memory 190, and/or the DSP 192 to effectuate operation of the communication device 180 and/or for presentation of content to a user of the communication device 180. In various embodiments of the invention, one or more clocks or reference signals provided to the Tx/Rx 184, the processor 188, the memory 190, and/or the DSP 192 may be generated via a PLL comprising a digitally programmable and/or calibrated voltage controlled ring oscillator.

FIG. 1B is a block diagram of an electronic device comprising an exemplary PLL, in accordance with an embodiment of the invention. Referring to FIG. 1B, the exemplary PLL 100 may comprise a phase detector 102, a charge pump 104, a loop filter 106, a voltage controlled ring oscillator 108, and a frequency divider 110.

The phase detector 102 may comprise suitable logic, circuitry, and/or code that may enable generating one or more signals based on a phase difference between two signals.

The charge pump 104 may comprise suitable logic, circuitry, and/or code that may enable sinking or sourcing a current 105 of the voltage controlled ring oscillator 108 based on the error signal 103.

The loop filter 106 may comprise suitable logic, circuitry, and/or code that may be operable to convert the current 105 output of the charge pump into a tuning voltage, V_{TUNE} 107.

The voltage controlled ring oscillator 108 may comprise suitable logic, circuitry, and/or code that may be operable to generate a signal 109 based on a tuning voltage 107. In this regard, the frequency of the signal 109 may be determined, at least in part, by the voltage 107. In various embodiments of the invention, the voltage controlled ring oscillator 108 may comprise a ring oscillator which may be operable to generate a periodic square wave. A frequency of the signal 109 output by such voltage controlled ring oscillator 108 may be determined by the number of activated or enabled stages of the voltage controlled ring oscillator 108 and the time delay of each stage. In this regard, aspects of the invention may enable dynamically adjusting the time delay of each stage in order to frequency calibrate the voltage controlled ring oscillator 108.

The frequency divider 110 may comprise suitable logic, circuitry, and/or code for receiving the signal 109 having a first, higher, frequency and outputting a feedback signal 111 having a second, lower, frequency. The frequency divider may be an integer and/or fractional divider and the divide ratio, K, may be determined based on the frequency of the output signal 109 and/or the frequency of the reference signal 115.

In operation, the input signal 115 and the feedback signal 111 may be input to the phase detector 102 to generate the error signal 103. The error signal 103 may be based on a phase difference between the signals 111 and 115. In this regard, the average voltage of the error signal 103 may be proportional to the phase difference between the signals 111 and 115. In instances that the error signal 103 indicates that feedback signal 111 is phase lagging the reference signal 115, the charge pump 104 may drive current into the loop filter 106. In instances that the error signal 103 indicates that feedback signal 111 is phase leading the reference signal 115, the charge pump 104 may draw current from the loop filter 106. The loop filter 106 may convert the current from the charge pump into the tuning voltage 107. The loop filter 106 may have a low pass frequency characteristic which may filter out noise or jitter and may prevent the tuning voltage 107 from over shooting which could lead to instability in the PLL and/or undesirable frequency fluctuations in the frequency of the output signal 109.

Thus, the input signal 115 may be of frequency Fᵢₙ and the PLL 100 may generate a signal 109 having a frequency of Fᵢₙ*K, where K is the divide ratio of the frequency divider 110. When the frequency of the output signal 109 is stable and equal, within a tolerance, to Fᵢₙ*K, the PLL 100 may be said to be in phase lock. In this regard, the range of frequencies of Fᵢₙ over which the PLL 100 may go from unlocked to phase lock may be referred to as the capture range. Similarly, the range of frequencies of Fᵢₙ over which the PLL may remain locked may be referred to as the lock range. The capture range and the lock range may be determined, at least in part, by the natural, or free-running, frequency of the voltage controlled ring oscillator 108, that is, the frequency of oscillation when the control terminal is left floating. Accordingly, aspects of the invention may enable digitally calibrating the natural frequency of the voltage controlled ring oscillator 108, and may thus enable digitally adjusting the capture range and/or lock range of the PLL 100.

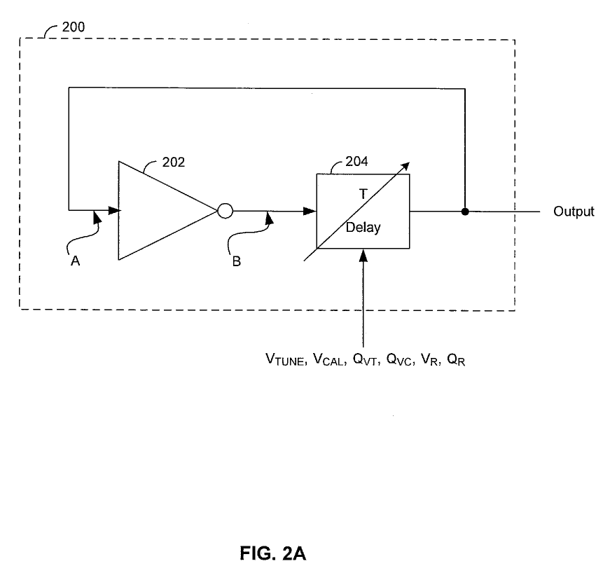

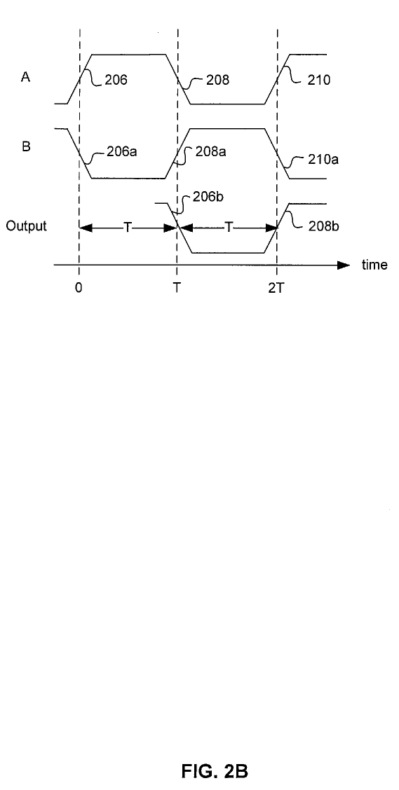

FIG. 2A is a block diagram illustrating an exemplary time-delay voltage-controlled oscillator, in accordance with an embodiment of the invention. Referring to FIG. 2A, there is shown a time-delay VCO 200, comprising an inverter 202 and a delay cell 204. There is also shown an output signal, a signal A at the input of the inverter, and a signal B at the output of the inverter. The output of the inverter 202 may be coupled to an output of the delay cell 204. The output of the delay cell 204 may be feedback to an input of the inverter 202. In various embodiments of the invention, one or more control voltages and/or digital control words may be input to the delay cell 204 to control a delay of the delay cell 204. Exemplary control voltages comprise: V_{TUNE} for finely adjusting one or more first varactors, V_{CAL} for finely adjusting one or more second varactors, and V_{R} for finely adjusting a resistance of one or more variable resistors. Exemplary digital control words comprise: Q_{VT} for coarsely adjusting one or more first varactors, Q_{VC} for coarsely adjusting one or more second varactors, and Q_{R} for coarsely adjusting a resistance of one or more variable resistors.

FIG. 2B is a diagram illustrating timing associated with the time-delay voltage controlled oscillator (VCO) of FIG. 2A, in accordance with an embodiment of the invention. Referring to FIG. 2B, there is shown the signal A, the signal B, and an output signal. The signal A is an input to the inverter 202, the signal B is an output of the inverter 202, and the output signal is generated by the voltage controlled delay cell 204. The signal A comprises amplitude transitions 206, 208 and 210, the signal B comprises amplitude transitions 206a, 208a and 210a and the output signal comprises amplitude transitions 206b and 208b.

In accordance with an embodiment of the invention, the operation of the time-delay VCO 200 may be explained by considering the signals A, B and output in response to an amplitude transition. The inverter 202 may be assumed to be instantaneous, that is, its output may invert its input without delay. Although physical devices may not be instantaneous, the delay of the inverter 202 may be considered included in the delay of the delay cell 204. The delay cell 204 may delay its input signal, signal B, by T seconds as illustrated in FIG. 2B, where T may be a function of V_{TUNE}, V_{CAL}, V_{R}, Q_{VT}, Q_{VC}, and/or Q_{R}, one or more of which may be applied to the delay cell 204.

With reference to FIG. 2A and FIG. 2B, at the input of the inverter 202, an amplitude transition 206 from low to high may occur for signal A at time 0. At the output of the inverter 202, the signal B may therefore transition from high to low as shown in amplitude transition 206a. Since the delay cell 204 may delay the signal B by T seconds, the amplitude transition 206a may only appear at the output at time T, depicted by transition 206b. Due to the instantaneous feedback from the output of the delay cell 204 back to the input of the inverter 202, signal A will transition from high to low and 206b may become transition 208 at signal A. This in turn may trigger the inverter 202 and toggle the inverter 202 output, as shown by the transition 208a. Due to the delay of the delay cell 204, the transition 208b may show up at the output signal at time 2T. This process may continue as described and may therefore produce a square-wave oscillator. The inverter 202 may have a gain greater than one to sustain oscillation. As illustrated in FIG. 2B, the output signal generated by the delay cell 204 has period 2T. Hence, the delay T may control the oscillation frequency of the time-delay VCO 200. By varying T via one or more of V_{TUNE}, V_{CAL}, V_{R}, Q_{VT}, Q_{VC}, and/or Q_{R}, the frequency of the time-delay VCO 200 may be adjusted.

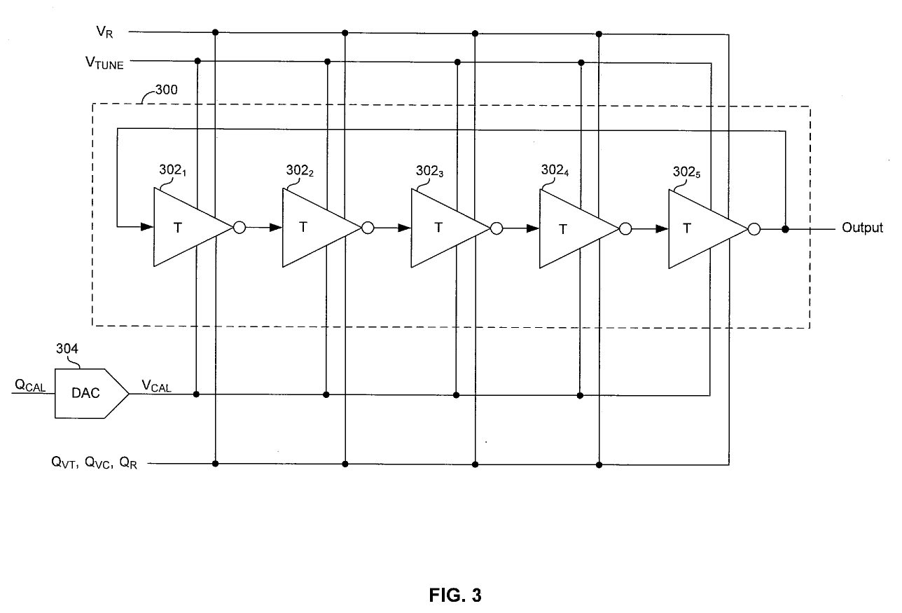

FIG. 3 is a block diagram illustrating an exemplary voltage-controlled ring oscillator comprising a plurality of oscillator stages, in accordance with an embodiment of the invention. Referring to FIG. 3, there is shown a voltage-controlled ring oscillator 300, comprising a plurality of oscillator stages 302₁, 302₂, 302₃, 302₄ and 302₅, referenced collectively or individually as oscillator stages 302. There is also shown in FIG. 3, a digital to analog converter 304.

Each of the oscillator stages 302₁, 302₂, 302₃, 302₄ and 302₅ may be substantially similar to the time-delay oscillator 200 described with respect to FIG. 2A. Although FIG. 3 depicts a 5-stage voltage controlled ring oscillator 300, the invention is not so limited and may comprise a voltage controlled ring oscillator having any odd number of stages.

The output of the oscillator stage 302₁ may be coupled to the input of the oscillator stage 302₂. The output of the oscillator stage 302₂ may be coupled to the input of the oscillator stage 302₃. The output of the oscillator stage 302₃ may be coupled to the input of the oscillator stage 302₄. The output of the oscillator stage 302₄ may be coupled to the input of the oscillator stage 302₅. The output of the oscillator stage 302₅ may be coupled to the input of the oscillator stage 302₁. The oscillator stages 302₁, 302₂, 302₃, 302₄ and 302₅ may each be coupled to one or more of V_{TUNE}, V_{CAL}, V_{R}, Q_{VT}, Q_{VC}, and/or Q_{R}. In various exemplary embodiments of the invention, one of more of V_{CAL} Q_{VT}, Q_{VC}, and Q_{R} may be utilized to coarsely control of the delay T of the oscillator stages 302 and one or both of V_{TUNE} and V_{R} may be utilized to finely control the delay T in the oscillator stages 302.

The DAC 304 may comprise suitable logic, circuitry, and/or code that may be operable to convert a digital word to an analog voltage. In this regard, the voltage V_{CAL} may be related to a control word Q_{CAL} by a transfer function of the DAC 304. For example, V_{CAL} may scale linearly or logarithmically with the value of Q_{CTRL}. The control word Q_{CAL} may be provided via, for example, a processor such as the processor 188 and/or a memory such as the memory 190, which is described with respect to FIG. 1A. In some embodiments of the invention, V_{R} may be similarly generated by a DAC such as the DAC 304.

The functionality of the voltage-controlled ring oscillator 300 may be similar to the time-delay oscillator 200, where the overall delay may be distributed over the plurality of oscillator stages. The oscillator stages 302 may each comprise an inverter 202 and a time delay cell 204 as illustrated in FIG. 2A. The output of an oscillator stage may be the negative of its input signal, delayed by T seconds. By combining five, in the exemplary embodiment depicted, oscillator stages, the overall delay of the voltage-controlled ring oscillator 300 may be the sum of the delays of the oscillator stages 302₁ through 302₅. The overall gain of the oscillator stages 302₁ through 302₅ may be greater than unity. The voltage-controlled ring oscillator 300 may be implemented with an arbitrary odd number of oscillator stages to enable the feedback signal to be an inverted and delayed copy of the input signal to the first oscillator stage, oscillator stage 302₁ as illustrated in FIG. 3. After an initial start-up period, the output signal of the voltage-controlled ring oscillator 300 may be a square wave with period 10T, since each oscillator stage may delay the signal by T seconds, introducing a total delay of 5 T seconds. As explained in FIG. 2B, the oscillating period may be twice the length of the total delay. In general, the period may be 2 NT seconds, where N may be the number of oscillator stages and T may be the delay of each oscillator stage.

Some implementations of voltage-controlled ring oscillators may use LC-circuits instead of ring the oscillators due to the high quality (Q) factor achievable. However, in accordance with various embodiments of the invention, the voltage controlled oscillators may be implemented in integrated circuits using ring oscillators since the ring oscillators utilize much less die area than LC-circuits because of the absence of inductors.

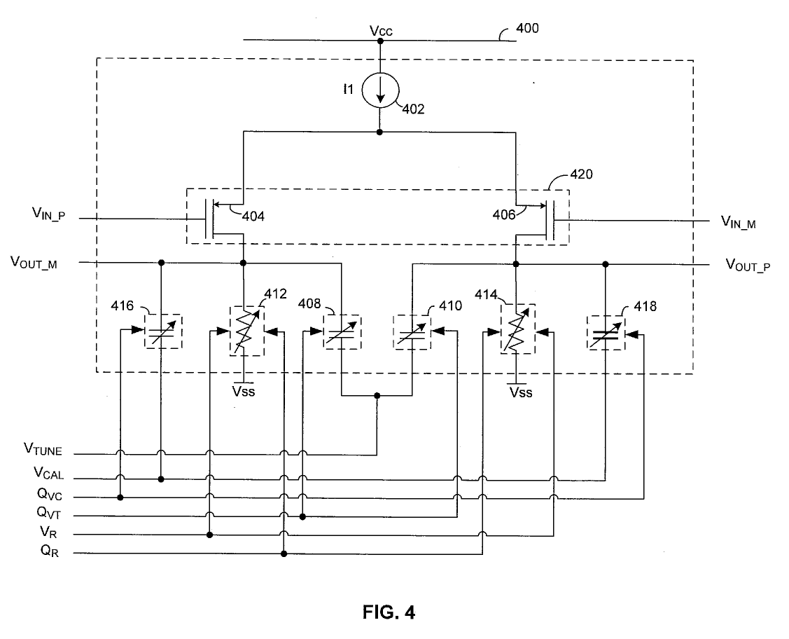

FIG. 4 is a circuit diagram illustrating an exemplary stage of a ring-oscillator, in accordance with an embodiment of the invention. Referring to FIG. 4, there is shown an oscillator stage 400 comprising a current source 402, a MOSFET differential pair 420 comprising MOSFETs 404 and 406, tuning varactors 408 and 410, variable resistors 412 and 414, and calibration varactors 416 and 418. There is also shown positive differential input voltage V_{IN}_{_{—}}_{P}; negative differential input voltage V_{IN}_{_{—}}_{M}; control voltages V_{TUNE}, V_{CAL}, and V_{R}; digital control words Q_{VT}, Q_{VC}, and Q_{R}; output signals V_{OUT}_{_{—}}_{M} and V_{OUT}_{_{—}}_{P}, and supply voltages Vcc and Vss.

The oscillator stage 400 may be an exemplary implementation of the oscillator stages 302 described with respect to FIG. 3. Additionally, the time-delay VCO 200 described with respect to FIG. 2A may be implemented via the oscillator stage 400 by coupling the output V_{OUT}_{_{—}}_{M} to the input V_{IN}_{_{—}}_{P} and coupling the output V_{OUT}_{_{—}}_{P} to the input V_{IN}_{_{—}}_{M}.

The input to the differential pair 420 may be differential voltage equal to V_{IN}_{_{—}}_{P}-V_{IN}_{_{—}}_{M}. The input signal V_{IN}_{_{—}}_{P} may be coupled to the gate of THE MOSFET 404. The source of the MOSFET 404 may be coupled to a first terminal of the current source 402. The second terminal of the current source 402 may be coupled to the supply voltage Vcc. The source of the MOSFET 404 may also be coupled to the source of the MOSFET 406. The input signal V_{IN}_{_{—}}_{M} may be coupled to the gate of the MOSFET 406. The drain of the MOSFET 406 may be coupled to a first terminal of the varactor 418, a first terminal of the variable resistor 414, and a first terminal of the varactor 410. The second terminal of the varactor 418 may be coupled to V_{CAL}. The second terminal of the variable resistor 414 may be coupled to Vss. The second terminal of the varactor 410 may be coupled to V_{TUNE}. The drain of the MOSFET 404 may be coupled to a first terminal of the varactor 416, a first terminal of the variable resistor 412, and a first terminal of the varactor 408. The second terminal of the varactor 416 may be coupled to V_{CAL}. The second terminal of the variable resistor 412 may be coupled to Vss. The second terminal of the varactor 408 may be coupled to V_{TUNE}. The output signal V_{OUT}_{_{—}}_{M} may be obtained at the drain of the MOSFET 404 and the output signal V_{OUT}_{_{—}}_{P} may be obtained at the drain of the MOSFET 406. The output may also be differential voltage equal to V_{OUT}_{_{—}}_{P}-V_{OUT}_{_{—}}_{M}.

In the exemplary embodiment of the invention depicted, the capacitance of the varactors 408 and 410 may be determined by V_{TUNE} and Q_{VT}. In this regard, V_{TUNE} may determine the voltage across the varactors 408 and 410 and Q_{VT} may control a size or configuration of the varactors 408 and 410. With regard to size or configuration, the varactors 408 and 410 may comprise, for example, a bank of varactor elements coupled via one or more switching elements where each switching element may be opened or closed based on a bit of Q_{VT}. Although varactors 408 and 410 are depicted as being controlled by V_{TUNE} and Q_{VT}, the invention is not so limited and one or both of V_{TUNE} and Q_{VT} may not be present. Similarly, one or both of V_{TUNE} and Q_{VT} may be a different form. For example, either signal may be analog or digital. Additionally, one or both of V_{TUNE} and Q_{VT} may be configured dynamically by, for example, a processor, or may be static and configured by a system designer or during manufacturing.

In the exemplary embodiment of the invention depicted, the capacitance of the varactors 416 and 418 may be determined by V_{CAL} and Q_{VC}. In this regard, V_{CAL} may determine the voltage across the varactors 416 and 418 and Q_{VC} may control a size or configuration of the varactors 416 and 418. With regard to size or configuration, the varactors 416 and 418 may comprise, for example, a bank of varactor elements coupled via one or more switching elements where each switching element may be opened or closed based on a bit of Q_{VC}. Although varactors 416 and 418 are depicted as being controlled by V_{CAL} and Q_{VC}, the invention is not so limited and one or both of V_{CAL} and Q_{VC} may not be present. Similarly, one or both of V_{CAL} and Q_{VC} may be a different form. For example, either signal may be analog or digital. Additionally, one or both of V_{CAL} and Q_{VC} may be configured dynamically by, for example, a processor, or may be static and configured by a system designer or during manufacturing.

In the exemplary embodiment of the invention depicted, the resistance of the variable resistors 412 and 414 may be determined by V_{R} and Q_{R}. For instance, the variable resistors 412 and 414 may each comprise a bank of MOS devices. In such an instance, V_{R} may be a gate voltage of the one or more MOS devices and Q_{R} may control one or more switching elements to couple or decouple the MOS devices from each other. Although variable resistors 412 and 414 are depicted as being controlled by V_{R} and Q_{R}, the invention is not so limited and one or both of V_{R} and Q_{R} may not be present. Similarly, one or both of V_{R} and Q_{R} may be a different form. For example, either signal may be analog or digital. Additionally, one or both of V_{R} and Q_{R} may be configured dynamically by, for example, a processor, or may be static and configured by a system designer or during manufacturing.

In various embodiments of the invention, the varactors 416 and 418 may have a relatively large capacitance and/or range of capacitance and the varactors 408 and 410 may have a relatively small capacitance and/or range of capacitance. Accordingly, the varactors 416 and 418 may be utilized for coarsely controlling the time delay of the oscillator stage 400 and varactors 408 and 410 may be utilized for finely controlling the time delay of the oscillator stage 400. In an exemplary embodiment of the invention, the coarse varactors 416 and 418 may be coarsely controlled by Q_{VC} and finely controlled by Q_{CAL} (after conversion to V_{CAL}), and the fine varactors 408 and 410 may be coarsely controlled by Q_{VT} and finely controlled by V_{TUNE}. Thus, there may be gradations of control of the frequency signals generated by the oscillator stage 400 where, of these four control words, Q_{VC} may provide a lowest resolution but widest range frequency control and V_{TUNE} may provide a highest resolution and but narrowest range frequency control.

In operation, V_{IN}_{_{—}}_{P} may initially be at a logic low voltage level and V_{IN}_{_{—}}_{M} may initially be at a logic high voltage level. Accordingly, MOSFET 404 may initially be acting like a closed switch and the MOSFET 406 may initially be acting like an open switch. Thus, the varactors 408 and 416 may initially be charged, that is, at a high(er) voltage, and the varactors 418 and 410 may initially be discharged, that is, at a low(er) voltage. In this regard, the high(er) voltage across varactors 408 and 416 may be depend on the on-resistance of the MOSFET 404, the resistance of the variable resistor 412, and the amount of time the varactors have to charge. Similarly, the low(er) voltage across varactors 418 and 410 may depend on the off-resistance of the MOSFET 406, the resistance of the variable resistor 414, and the amount of time the varactors 418 and 410 have to discharge. Subsequently, V_{IN}_{_{—}}_{P} may transition to a logic high voltage level and V_{IN}_{_{—}}_{M} may transition to a logic low voltage level. Consequently, the MOSFET 404 may act like an open switch and the MOSFET 406 may act like a closed switch. Hence, the varactors 408 and 416 may begin discharging to a low(er) voltage through the variable resistor 412 and the current 11 through the MOSFET 406 may begin charging varactors 418 and 410 to a high(er) voltage. In this regard, the high(er) voltage across the varactors 418 and 410 may be depend on the on-resistance of the MOSFET 406, the resistance of the variable resistor 414, and the amount of time the varactors 418 and 410 have to charge. Similarly, the low(er) voltage across varactors 408 and 416 may depend on the off-resistance of the MOSFET 404, the resistance of the variable resistor 412, and the amount of time the varactors 408 and 416 have to discharge.

As the varactors 408 and 416 discharge, the voltage of V_{OUT}_{_{—}}_{M} may begin to decrease and eventually may reach a logic low level. The time constant for discharging V_{OUT}_{_{—}}_{M} may be (R412*(C408+C416)), where R412 is the resistance of the variable resistor 412, C408 is the capacitance of the varactor 408, and C416 is the capacitance of the varactor 416.

As the varactors 410 and 418 charge, the voltage of V_{OUT}_{_{—}}_{P} may begin to increase and eventually may reach a logic high level. The time constant for charging V_{OUT}_{_{—}}_{P} may be (R406*(C410+C418)), where R406 is the on-resistance of the MOSFET 406, C410 is the capacitance of the varactor 410, and C418 is the capacitance of the varactor 418.

A transition of V_{IN}_{_{—}}_{P} back to a logic low voltage level and V_{IN}_{_{—}}_{M} back to a logic high voltage level may proceed in a similar manner. In this regard, the charging time constant of V_{OUT}_{_{—}}_{M} may be (R404*(C408+C416)), where R404 is the on-resistance of the MOSFET 404, C408 is the capacitance of the varactor 408, and C416 is the capacitance of the varactor 416. The discharging time constant of V_{OUT}_{_{—}}_{P} may be (R414*(C410+C418)) where R414 is the resistance of the resistor 414, C410 is the capacitance of the varactor 410, and C418 is the capacitance of the varactor 418.

Thus, due to the charging and discharging time constants, there may be a time delay between transitions on the inputs, V_{IN}_{_{—}}_{P} and V_{IN}_{_{—}}_{M}, and transitions on the outputs, V_{OUT}_{_{—}}_{P} and V_{OUT}_{_{—}}_{M}. Moreover, the delay may depend on the capacitance of the varactors 408, 410, 416, and 418. Accordingly, controlling the capacitance of the varactors 408, 410, 416, and 418 may enable controlling the time delay of the oscillator stage 400 and thus controlling the frequency of a time-delay oscillator or ring-oscillator comprising one or more of the stages 400.

In various embodiments of the invention the resistance of the resistors 412 and 414 and the capacitance of the varactors 408, 410, 416, and 418 may be tuned such that the charge and discharge times of V_{OUT}_{_{—}}_{P} and V_{OUT}_{_{—}}_{M} are approximately the same. In this manner, positive and negative values of the differential output between V_{OUT}_{_{—}}_{P} and V_{OUT}_{_{—}}_{M} may be approximately symmetric. Furthermore, adjustment of the resistors 412 and 414 may enable improved amplitude stability that may reduce phase noise compared to conventional VCOs.

In accordance with various embodiment of the invention, the oscillator stage 400 may not utilize any inductors. Since the time delay of the oscillator stage 400 may be controlled by one or more of V_{TUNE}, V_{CAL}, V_{R}, Q_{VT}, Q_{VC}, and/or Q_{R}, the oscillator stage 400 may avoid a voltage-to-current conversion circuit that may be required for some implementations of voltage-controlled ring oscillators. Due to a reduced number of components of this embodiment of the invention when compared to some implementations of voltage-controlled ring oscillators, phase noise may be substantially reduced.

The gain of a voltage-controlled ring oscillator, Kvco, may be a function of the oscillator stage 400. By lowering Kvco, the range of frequencies over which a PLL comprising one or more instantiations of the oscillator stage 400 may operate may be reduced since the frequency range of the PLL may be proportional to the gain Kvco. Kvco of the oscillator stage 400 may be proportional to C_{V}/(C_{V}+C_{F}), where C_{V} may be the capacitance (C408+C416) or (C410+C418), and C_{F} may be parasitic capacitance at the output node V_{OUT}_{_{—}}_{P} or V_{OUT}_{_{—}}_{M}. Accordingly, the gain Kvco may be varied by varying the capacitance of the varactors 408, 410, 416, and 418. A reduced Kvco may also permit use of physically smaller components in a loop filter of a PLL comprising one or more instantiations of the oscillator 400.

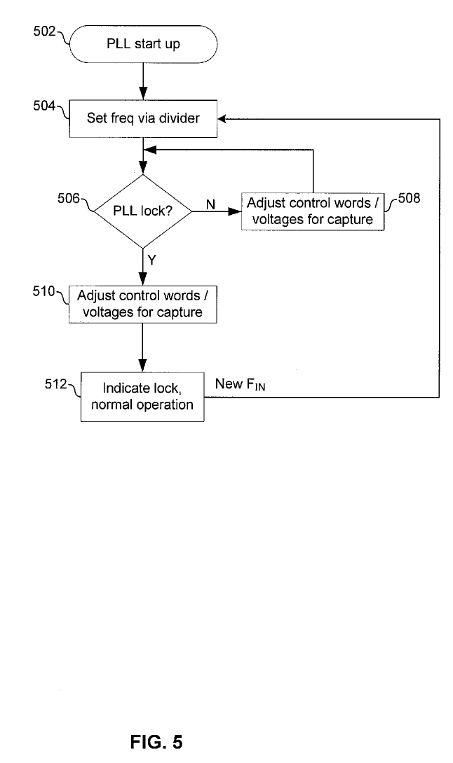

FIG. 5 is a flowchart illustrating frequency calibration of a PLL comprising a voltage controlled ring oscillator, in accordance with an embodiment of the invention. Referring to FIG. 5, the exemplary steps may begin at step 502 with start-up of the PLL 100. In this regard, a supply voltage may be applied to the PLL 100, an input signal 115 (FIG. 1B) of frequency Fᵢₙ may be applied to the PLL 100, the PLL 100 may begin generating an output signal 109 (FIG. 1B), and the PLL 100 may attempt to achieve phase lock. Subsequent to step 502, the exemplary steps may advance to step 504.

In step 504, the divide ratio K of the frequency divider 110 (FIG. 1B) may be programmed, where K may be determined based on Fᵢₙ and a desired frequency, F_{OUT}, of the output signal 109. For example, a look-up table may be utilized to determine the expected digital value of K for a given input frequency Fᵢₙ and desired output frequency Fₒᵤₜ. In this regard, the desired output frequency Fₒᵤₜ may equal to, within a tolerance, K*Fᵢₙ. Subsequent to step 504, the exemplary steps may advance to step 506

In step 506, it may be determined whether the PLL 100 is able achieve phase lock as configured. That is, the PLL 100 may attempt to achieve phase lock with default values of V_{CAL}, V_{R}, Q_{VT}, Q_{VC}, and Q_{R}, assuming each signal is present in the particular implementation of the voltage-controlled ring oscillator 108. V_{CAL}, V_{R}, Q_{VT}, Q_{VC}, and Q_{R} may be set to their default values upon start-up of the PLL 100. The default value of V_{CAL}, V_{R}, Q_{VT}, Q_{VC}, and Q_{R} may be configured by system designers, and/or digitally configured via the processor 188, DSP 192, memory 190, and/or user controls 185 described with respect to FIG. 1A. The default values of V_{CAL}, V_{R}, Q_{VT}, Q_{VC}, and Q_{R} may depend on a mode of operation of a device, such as the device 180, in which the PLL 100 operates. If phase lock is achieved, the exemplary steps may advance to step 510.

In step 510, the lock range of the PLL 100 for the current value of Fᵢₙ may be determined. For example, a range of values of one or more of V_{CAL}, V_{R}, Q_{VT}, Q_{VC}, and Q_{R} for which phase lock is maintained may be determined, and one or more of V_{CAL}, V_{R}, Q_{VT}, Q_{VC}, and Q_{R} may accordingly be set at the center of the determined range. Subsequent to step 510, the exemplary steps may advance to step 512.

In step 512, a signal indicating that the PLL 100 has achieved phase lock may be asserted and one or more circuits utilizing the PLL 100 may begin normal operation. While phase locked, the frequency of the output signal 109 may track the frequency of the input signal 115. In this regard, if F_{IN} changes by Δ, then F_{OUT} may change by Δ*K, as long as Δ is within the lock range of the PLL. When a new input frequency not within the lock range of the PLL 100 is selected for the input signal 115, the exemplary steps may return to step 504. In various embodiments of the invention, in order to prevent instability and/or over-correcting, one or more of V_{CAL}, V_{R}, Q_{VT}, Q_{VC}, and Q_{R} may be adjusted once the PLL 100 has been unlocked for longer than a certain amount of time. The amount of time may be dependent on, for example, a frequency of the input signal 115 and/or a mode of operation of a device, such as the device 180 described with respect to FIG. 1, in which the PLL 100 resides.

Returning to step 506, in instances that phase lock cannot be achieved, the exemplary steps may advance to step 508. In step 508, the voltage controlled ring oscillator 108 may be calibrated such that Fᵢₙ is within the capture range of the PLL 100. In this regard, due to process, temperature, and/or voltage variations, there may be instances when no possible values of V_{TUNE} 107 may be able to achieve phase lock. In such instances, the voltage controlled ring oscillator 108 may need to be calibrated. Accordingly, one or more of V_{CAL}, V_{R}, Q_{VT}, Q_{VC}, and Q_{R} may be changed to adjust the time delay of the stages of the voltage controlled ring oscillator 108. The stages of the voltage controlled ring oscillator may be substantially similar to the stages 302 described with respect to FIG. 3. Thus, a range of values of one or more of V_{CAL}, V_{R}, Q_{VT}, Q_{VC}, and Q_{R} may be swept to adjust the frequency of the voltage controlled ring oscillator 108 until phase lock may be achieved. Subsequently to step 508, the exemplary steps may return to step 506.

Aspects of a method and system for frequency calibration of a voltage controlled ring oscillator are provided. In an exemplary embodiment of the invention, an oscillating voltage, V_{OUT}_{_{—}}_{P}-V_{OUT}_{_{—}}_{M}, may be generated via a voltage controlled ring oscillator 300 comprising a plurality of delay cells 400. Each of the plurality of delay cells 400 may comprise a MOSFET differential pair 420 coupled to variable resistors 412 and 414. A frequency of oscillation and amplitude of the generated oscillating voltage, V_{OUT}_{_{—}}_{P}-V_{OUT}_{_{—}}_{M}, may be controlled by controlling a resistance of the variable resistors 412 and 414. The MOSFET differential pair 420 may be controlled via a differential input voltage, V_{IN}_{_{—}}_{P}-V_{IN}_{_{—}}_{M}. In this regard, the differential input voltage, V_{IN}_{_{—}}_{P}-V_{IN}_{_{—}}_{M}, of each delay cell 400 may be an output voltage, V_{OUT}_{_{—}}_{P}-V_{OUT}_{_{—}}_{M}, of another delay cell 400. The frequency of oscillation and amplitude of V_{OUT}_{_{—}}_{P}-V_{OUT}_{_{—}}_{M} may be controlled via one or more digital control words, such as Q_{CAL}, Q_{VT}, Q_{VC}, and Q_{R}, generated by one or more of a baseband processor 188, a DSP 192, and a memory 190.

The digital control words may comprise a control word, such as Q_{VT}, for finely adjusting a frequency of the oscillating voltage V_{OUT}_{_{—}}_{P}-V_{OUT}_{_{—}}_{M} and a control word, such as Q_{CAL}, Q_{VC}, and Q_{R}, for coarsely tuning the oscillating voltage V_{OUT}_{_{—}}_{P}-V_{OUT}_{_{—}}_{M}. The one or more digital control words may be retrieved from a look-up table. The one or more digital control words may be initialized to a default value. The one or more control words may be adjusted such that a lock range of a phase locked loop 100 utilizing the voltage controlled ring oscillator 300 may be centered on a frequency of an input signal 115 of the phase locked loop 100. The one or more control words may be swept over a range of values until a phase locked loop 100 utilizing the voltage controlled ring oscillator 300 is phase locked. The one or more digital control words may be adjusted via a feedback path of a phase locked loop 100 utilizing the voltage controlled ring oscillator 300.

Another embodiment of the invention may provide a machine and/or computer readable storage and/or medium, having stored thereon, a machine code and/or a computer program having at least one code section executable by a machine and/or a computer, thereby causing the machine and/or computer to perform the steps as described herein for frequency calibration of a voltage controlled ring oscillator.

Accordingly, the present invention may be realized in hardware, software, or a combination of hardware and software. The present invention may be realized in a centralized fashion in at least one computer system, or in a distributed fashion where different cells are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for signal processing, the method comprising:
generating an oscillating voltage via a voltage controlled ring oscillator comprising a plurality of delay cells, wherein each of said plurality of delay cells comprises a MOSFET differential pair coupled to a plurality of variable resistors;
controlling a frequency of oscillation and amplitude of said generated oscillating voltage by controlling a resistance of said plurality of variable resistors.

2. The method according to claim 1, wherein said MOSFET differential pair is controlled via a differential input voltage.

3. The method according to claim 2, wherein a differential input voltage of each of said plurality of delay cells is an output voltage of another of said plurality of delay cells.

4. The method according to claim 1, comprising digitally controlling said frequency of oscillation and said amplitude of said one or more of delay cells via one or more digital control words generated by one or more of a baseband processor, a DSP, and a memory.

5. The method according to claim 4, wherein said digital control words comprise:
one or more first control words for a higher resolution tuning of said frequency of oscillation and said amplitude; and
one or more second control words for a lower resolution tuning of said frequency of oscillation and said amplitude.

6. The method according to claim 4, comprising retrieving said generated one or more digital control words from a look-up table (LUT) within said memory.

7. The method according to claim 4, comprising initializing said one or more digital control words to a default value.

8. The method according to claim 4, comprising adjusting said one or more digital control words such that a lock range of a PLL utilizing said voltage controlled ring oscillator is centered on a frequency of an input signal of said phase locked loop.

9. The method according to claim 4, comprising sweeping said one or more digital control words over a range of values until a phase locked loop utilizing said voltage controlled ring oscillator is phase locked.

10. The method according to claim 1, wherein said frequency of oscillation is adjusted via a feedback path of a phase locked loop utilizing said voltage controlled ring oscillator.

11. A system for signal processing, the system comprising:
one or more circuits comprising a voltage controlled ring oscillator comprising a plurality of delay cells, wherein each of said plurality of delay cells comprises a MOSFET differential pair coupled to a plurality of variable resistors;
said one or more circuits are operable to generate an oscillating voltage at an output of said voltage controlled ring oscillator;
said one or more circuits are operable to control a frequency of oscillation and an amplitude said generated oscillating voltage by controlling a resistance of said plurality of variable resistors.

12. The system according to claim 11, wherein said MOSFET differential pair is controlled via a differential input voltage.

13. The system according to claim 1 system 12, wherein a differential input voltage of each of said plurality of delay cells is an output voltage of another of said plurality of delay cells.

14. The system according to claim 11, wherein said one or more circuits comprise a baseband processor, a DSP, and/or a memory, and said one or more circuits are operable to generate one or more digital control words to digitally control said frequency of oscillation and said amplitude.

15. The system according to claim 14, wherein said digital control words comprise:
one or more first control words for a higher resolution tuning of said frequency of oscillation and said amplitude; and
one or more second control words for a lower resolution tuning of said frequency of oscillation and said amplitude.

16. The system according to claim 14, wherein said one or more digital control words are retrieved from a look-up table (LUT) within said memory.

17. The system according to claim 14, wherein said one or more digital control words are initialized to a default value.

18. The system according to claim 14, wherein said one or more circuits are operable to adjust said one or more digital control words such that a lock range of a PLL utilizing said voltage controlled ring oscillator is centered on a frequency of an input signal of said phase locked loop.

19. The system according to claim 14, wherein said one or more circuits are operable to sweep said one or more digital control words over a range of values until a PLL utilizing said voltage controlled ring oscillator is phase locked.

20. The system according to claim 11, wherein said frequency of oscillation is adjusted via a feedback path of a PLL utilizing said voltage controlled ring oscillator.
